(19) United States
(12) Patent Application Publication
(10) Pub. No.: US 2026/0259384 A1
(43) Pub. Date: Sep. 3, 2026

(54) OIO CHIPLET AND AI COMPUTING CLUSTER

(71) Applicant: Suzhou Qidian Guangzi Co., Ltd., Suzhou (CN)

(72) Inventors: Chongjin Xie, Suzhou (CN); Miaofeng Li, Suzhou (CN); Jun Zhou, Suzhou (CN)

(21) Appl. No.: 19/551,651

(22) Filed: Feb. 27, 2026

(30) Foreign Application Priority Data
Feb. 28, 2025 (CN) 202510231311.7

(51) Int. Cl. G02B 6/43; G02B 6/12; G02B 6/42; H10W 90/20

(52) U.S. Cl. CPC G02B 6/43; G02B 6/12004; G02B 6/428; H10W 90/295

(57) ABSTRACT

Disclosed are an OIO chiplet and an AI computing cluster, applied in the technical field of optoelectronic transmission, where the OIO chiplet includes photonic chips, electronic chips, and a microcontroller chip, or a microcontroller application-specific integrated circuit. The photonic chip, the electronic chip, and control units are packaged into a single OIO chiplet, and the chiplet operates independently as an OIO. Analog optical and electrical equalization technologies are applied in the photonic chip and the electronic chip to enhance system bandwidth and linearity. The chiplet is applied to a Scale-up network inside the node for interconnects among GPUs.

### CROSS-REFERENCE TO THE RELATED APPLICATION

The present disclosure claims the priority to the Chinese patent application with the filing No. 2025102313117 filed with the China National Intellectual Property Administration on Feb. 28, 2025, and entitled “OIO CHIPLET AND AI COMPUTING CLUSTER”, contents of which are incorporated herein by reference in entirety.

### TECHNICAL FIELD

The present disclosure relates to the technical field of optoelectronic transmission, and specifically, to an OIO chiplet and an AI computing cluster.

### BACKGROUND

Currently, artificial intelligence (AI) has become a focus of social attention, and AI not only attracts attention from the scientific and technological community, but also draws attention from the whole society. Due to increasing numbers of AI participants, increasingly complex models, and increasing parameters, market demand for AI computing clusters is continuously increasing. AI computing is a large-scale parallel computing, and an AI cluster is typically composed of a large number of Graphics Processing Units (GPUs) with various of interconnects, including interconnects of a front-end network, interconnects of a back-end Scale-out network, and interconnects of a back-end Scale-up network.

The Scale-up network is mainly an interconnect network used for inter-chip communications, particularly interconnects among GPUs. The Scale-up network can implement direct interconnects between GPU chips, and implement pooling and resource sharing between a GPU and a memory chip (for example, HBM-High Bandwidth Memory). The expansion of a scale of the Scale-up network can greatly improve computing efficiency of an AI computing cluster. However, in the prior art, the size of Scale-up network is limited by bandwidth limitation of copper cables, and size, latency, power consumption and reliability limitation of pluggable optical transceivers, resulting in difficulty in enlarging a scale of the Scale-up network and limitation in improvement of computing efficiency of a computing node.

### SUMMARY

An objective of the present disclosure is to provide an Optical Input Output (OIO) chiplet and an AI computing cluster, so as to solve the above problems existing in the prior art.

According to a first aspect, a first OIO chiplet is provided, which includes:

photonic chips, where the photonic chip includes photodetectors and photonic modulators, the photodetector is configured to receive an optical signal, the photonic modulator modulates an input continuous-wave light according to an input electrical signal and outputs an optical signal, and the photonic modulator improves bandwidth through analog equalization;

electronic chips, where the electronic chip includes driver amplifiers, transimpedance amplifiers, and application-specific integrated circuits, the driver amplifier provides a driving signal for the photonic modulator, the transimpedance amplifier amplifies an electrical signal generated by the photodetector, and the application-specific integrated circuit includes an analog equalization module configured to improve linearity of the driver amplifier and the transimpedance amplifier;

a microcontroller chip, where the microcontroller chip is connected to feedback terminals of the photodetector and the photonic modulator, and sends control signals to the photodetector and the photonic modulator to adjust output; and

an interposer, where the photonic chip, the electronic chip, and the microcontroller chip are stacked on the interposer in a form of bare die, and inter-chip communication is implemented using through-silicon vias or through-mold vias.

In an optional embodiment, the photonic modulator includes a traveling-wave electrode and an active region, the traveling-wave electrode is divided into a plurality of segments having a same length, and each segment of the traveling-wave electrode loads an active region having a different capacitance or impedance to form a gradient.

In an optional embodiment, the analog equalization module includes a plurality of equalizers, the driver amplifier and the transimpedance amplifier include a plurality of cascaded amplification stages, and each amplification stage is provided with one equalizer.

In an optional embodiment, the photonic chip is disposed on the interposer, through-silicon vias are disposed in the photonic chip, and the microcontroller chip and the electronic chip are disposed on the photonic chip.

In an optional embodiment, the electronic chip and the microcontroller chip are disposed on the interposer, through-silicon vias are disposed in the electronic chip, and the photonic chip is disposed on the electronic chip and the microcontroller chip.

According to a second aspect, a second OIO chiplet is provided, which includes:

photonic chips, where the photonic chip includes photodetectors and photonic modulators, the photodetector is configured to receive an optical signal, the photonic modulator modulates a continuous-wave light generated by a laser according to an input electrical signal and outputs the optical signal, and the photonic modulator improves bandwidth through analog equalization;

electronic chips, where the electronic chip includes driver amplifiers, transimpedance amplifiers, and application-specific integrated circuits, the driver amplifier provides a driving signal for the photonic modulator, the transimpedance amplifier amplifies an electrical signal generated by the photodetector, and the application-specific integrated circuit includes an analog equalization module configured to improve linearity of the driver amplifier and the transimpedance amplifier and a microcontrol circuit, where the microcontrol circuit is connected to feedback terminals of the photodetector and the photonic modulator, and sends control signals to the photodetector and the photonic modulator to adjust output; and

an interposer, where the photonic chip and the electronic chip are stacked on the interposer in a form of bare die, and inter-chip communication is implemented using through-silicon vias or through-mold vias.

In an optional embodiment, the photonic modulator includes a traveling-wave electrode and an active region, the traveling-wave electrode is divided into N segments having a same length, and each segment of the traveling-wave electrode loads an active region having a different capacitance or impedance to form a gradient.

In an optional embodiment, the analog equalization module includes a plurality of equalizers, the driver amplifier and the transimpedance amplifier include a plurality of cascaded amplification stages, and each amplification stage is provided with one equalizer.

In an optional embodiment, the photonic chip is disposed on the interposer, through-silicon vias are disposed in the photonic chip, and the electronic chip is disposed on the photonic chip.

In an optional embodiment, the electronic chip is disposed on the interposer, through-silicon vias are disposed in the electronic chip, and the photonic chip is disposed on the electronic chip.

According to a third aspect, an AI computing cluster is provided, which includes a plurality of nodes, each node includes a plurality of GPUs, the nodes are interconnected through a Scale-out network, the nodes are internally interconnected through a Scale-up network, GPUs within the nodes are interconnected through a fiber array and the OIO chiplet according to the first aspect or the second aspect, and the fiber array is connected to a corresponding OIO chiplet.

In an optional embodiment, the OIO chiplet and a corresponding GPU are disposed on a same PCB, and the OIO chiplet is packaged on the PCB through a ball grid array or land grid array.

In an optional embodiment, the GPU and a corresponding OIO chiplet are packaged on a same substrate.

The present disclosure has the following beneficial effects.

The present disclosure packages photonic chips, electronic chips, and MCUs into one OIO chiplet, and the chiplet independently operates as OIO, thereby greatly increasing an interconnect distance, enlarging a Scale-up network scale of GPU interconnection, and providing advantages of low latency, low power consumption, high bandwidth density, and high reliability. The present disclosure adopts analog optical equalization and analog electrical equalization technologies in the photonic chip and the electronic chip, thereby improving system bandwidth and linearity, and enabling normal operation of high-speed transmission of a channel without a DSP.

### BRIEF DESCRIPTION OF THE DRAWINGS

To more clearly illustrate the technical solutions of the embodiments of the present disclosure, the drawings required in the embodiments of the present disclosure will be briefly described below. It should be understood that the following drawings only illustrate some embodiments of the present disclosure and therefore should not be considered as limitations of the scope. For those of ordinary skill in the art, other related drawings can be obtained according to these drawings without creative efforts.

FIG. 1 is a schematic diagram of copper cable interconnect adopted by a conventional Scale-up network according to an embodiment of the present disclosure;

FIG. 2 is a schematic diagram of a pluggable optical transceiver interconnect solution adopted by a conventional Scale-up network according to an embodiment of the present disclosure;

FIG. 3 is an architectural diagram of an AI cluster according to an embodiment of the present disclosure;

FIG. 4 is a schematic diagram of a back-end Scale-up network in an AI cluster according to an embodiment of the present disclosure;

FIG. 5 is a functional block diagram of one OIO chiplet according to an embodiment of the present disclosure;

FIG. 6 is a schematic diagram of an equalization principle of a photonic chip of an OIO chiplet according to an embodiment of the present disclosure;

FIG. 7 is a schematic diagram of an equalization principle of an electronic chip of an OIO chiplet according to an embodiment of the present disclosure;

FIG. 8 is a diagram illustrating a bandwidth extension effect after adoption of analog equalization in a photonic chip and an electronic chip according to an embodiment of the present disclosure;

FIG. 9 is a schematic diagram of one packaging structure of an OIO chiplet according to an embodiment of the present disclosure;

FIG. 10 is a schematic diagram of one packaging structure of an OIO chiplet according to an embodiment of the present disclosure;

FIG. 11 is a functional block diagram of one OIO chiplet according to an embodiment of the present disclosure;

FIG. 12 is a schematic diagram of one packaging structure of an OIO chiplet according to an embodiment of the present disclosure;

FIG. 13 is a schematic diagram of one packaging structure of an OIO chiplet according to an embodiment of the present disclosure; and

FIG. 14 is a schematic diagram of the connection between GPUs in an AI computing cluster according to an embodiment of the present disclosure.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are only a part rather than all of the embodiments of the present disclosure. All other embodiments obtained by those of ordinary skill in the art based on embodiments of the present disclosure without creative efforts shall fall within the protection scope of the present disclosure. Unless otherwise defined, technical terms or scientific terms used in the present disclosure shall have meanings commonly understood by those of ordinary skill in the art to which the present disclosure pertains. The terms such as "first", "second", and similar terms used in the present disclosure do not indicate any order, quantity, or importance, but are merely used to distinguish different components. The terms such as "comprise" or "include" and similar terms indicate that elements or items appearing before such terms encompass elements or items listed after such terms and equivalents thereof, and do not exclude other elements or items. The terms such as "connected", "coupled", or "connected to" and similar terms are not limited to physical or mechanical connection, but may include electrical connection, whether direct or indirect. The terms such as "upper", "lower", "left", and "right" are only used to indicate relative positional relationships, and after an absolute position of a described object changes, the relative positional relationships may correspondingly change.

For facilitating better understanding of the present disclosure by those skilled in the art, technical terms involved in the present disclosure are briefly introduced below.

An OIO chiplet (Optical Input Output Chiplet) is a chiplet integrating an Optical Input Output (OIO) function. An OIO chiplet transmits data using optical signals, and the OIO chiplet has the following advantages: (1) high-speed communication: providing higher bandwidth than a conventional electrical interface; (2) low latency: absence of signal processing delay in the OIO chiplet, thereby greatly reducing interconnection latency; (3) low power consumption: adoption of analog signal processing technology, resulting in power consumption greatly lower than current optical modules; and (4) modular design: flexible combination to adapt to different application scenarios and requirements.

A Scale-up network is an interconnect network for inter-chip communication, which expands network performance by enhancing capabilities of network devices or infrastructure, and improves computing capability of a super-node and computing efficiency of a cluster. The Scale-up network has the following advantages: (1) enhancing performance of a super-node: for example, improving performance of a super-node by pooling and sharing resources of computing chips and memory chips; (2) optimizing network architecture: for example, optimizing network architecture by improving routing algorithms and protocol stacks; and (3) integrating more efficient technologies: for example, achieving more efficient data transmission by using faster network interfaces or more advanced switches.

An AI computing cluster is a group of high-performance computer systems specially designed to accelerate AI model training and inference. The AI computing cluster accelerates complex computing tasks on large-scale datasets through parallel processing. The components of an AI computing cluster include: (1) a plurality of nodes, each node is a physical or virtual computing unit in the cluster, including: a central processing unit (CPU), configured to execute general-purpose computing tasks; a graphics processing unit (GPU), proficient in processing parallel computing tasks and widely configured to train deep learning models; and a tensor processing unit (TPU), a dedicated hardware accelerator specially designed for machine learning; (2) memory and storage, including high-bandwidth memory (HBM), large-capacity memory (RAM), and high-speed storage devices such as solid-state drives (SSD), to support efficient data reading and writing; (3) an interconnect network, configured for high-speed communication between nodes, where nodes are interconnected through a Scale-out network, and GPUs are interconnected through a Scale-up network adopting OIO chiplets; and (4) a management node, configured to manage and schedule the AI computing cluster as a whole, including resource allocation, task scheduling, and monitoring. A workflow of the AI computing cluster includes: (1) task submission, where a user submits an AI model training or inference task to a cluster management system; (2) task scheduling, where the management system automatically allocates the task to a suitable node for execution according to current resource usage; (3) data distribution, where a dataset is distributed to nodes to ensure that each node has access to required data; (4) parallel computing, where the nodes execute computing tasks in parallel and use multi-core CPUs, GPUs, or TPUs for acceleration; and (5) result aggregation, where after completion of computing, results from the nodes are aggregated and integrated to form a final output. The AI computing cluster has the following advantages: (1) high efficiency: significantly shortening training time through parallel computing and improving model iteration speed; (2) scalability: enabling flexible expansion of cluster scale based on a requirement, and adding more nodes to handle larger computing tasks; (3) resource sharing: allowing a plurality of users or projects to share the same cluster resources, thereby improving resource utilization; and (4) cost-effectiveness: completing more computing tasks per unit time compared with a single-machine configuration, thereby reducing overall cost. In view of the above advantages, the AI computing cluster is widely applied in the following scenarios: (1) deep learning model training, such as image recognition, natural language processing (NLP), speech recognition, ChatGPT (Chat Generative Pre-trained Transformer), and other large language models (LLM); (2) autonomous driving, training complex perception and decision-making models to achieve safety and reliability of autonomous vehicles; (3) medical image analysis, analyzing medical images through deep learning algorithms to assist physicians in diagnosis; (4) financial risk prediction, performing risk assessment and market forecasting using large-scale datasets; and (5) natural science research, performing complex computational tasks in fields such as climate simulation and astrophysics.

After introducing technical terms involved in the present disclosure, the application scenarios and design concepts of the present disclosure are briefly described.

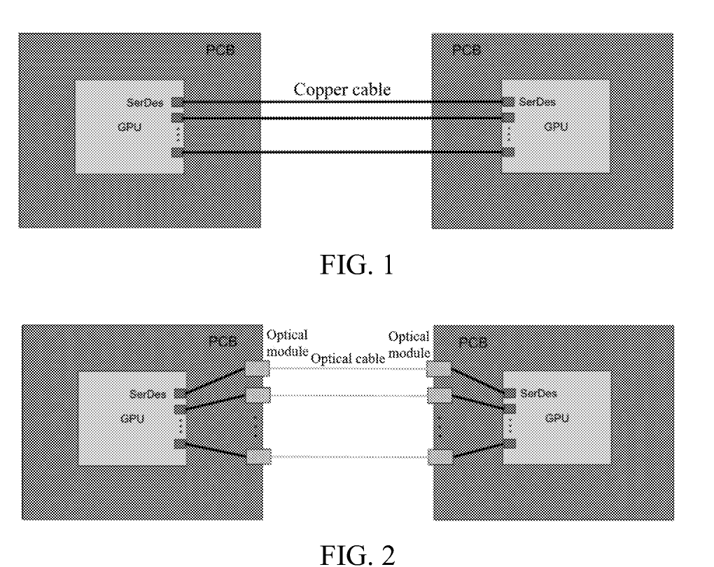

In a conventional Scale-up network, as shown in FIG. 1, the interconnect among GPUs can be implemented using a copper cable. Because the copper cable has limited bandwidth and a restricted transmission distance, the interconnect distance of the copper cable is limited within a single rack. Since the Scale-up network is spatially confined within a single rack, the power consumption of the rack increases significantly, causing great difficulty in rack power supply and heat dissipation, and a scale of the Scale-up network implemented by such copper cable interconnect is difficult to be enlarged, thereby limiting improvement of computing efficiency of computing nodes. In another Scale-up network, as shown in FIG. 2, the interconnect among GPUs can be implemented using a pluggable optical transceiver and an optical cable. The adoption of the optical transceiver can greatly increase interconnect distance, achieve cross-rack interconnect of the Scale-up network, and enlarge the scale of the Scale-up network. However, currently, the pluggable optical transceiver cannot meet higher requirements brought by improvement of computing efficiency in the Scale-up network in terms of latency, power consumption, and cost. In addition, the optical transceiver is usually disposed at a motherboard edge, occupying a certain space and possibly limiting miniaturized design of the system. As shown in FIGS. 1 and 2, the interconnect between a GPU and another GPU is implemented directly. In practical applications, interconnect among GPUs can also be routed through a switch.

To this end, an embodiment of the present disclosure packages photonic chips, electronic chips, and MCUs into one OIO chiplet, and the chiplet independently operates as OIO. Compared with a copper cable interconnect solution, the OIO chiplet can greatly increase interconnect distance and enlarge a Scale-up network scale of GPU interconnect. Compared with a conventional pluggable optical transceiver interconnect solution, the OIO chiplet provides the advantages of low latency, low power consumption, high bandwidth density, and high reliability. The analog optical equalization and analog electrical equalization technologies are adopted in the photonic chip and the electronic chip, thereby improving system bandwidth and linearity and enabling normal operation of high-speed channel transmission without a DSP.

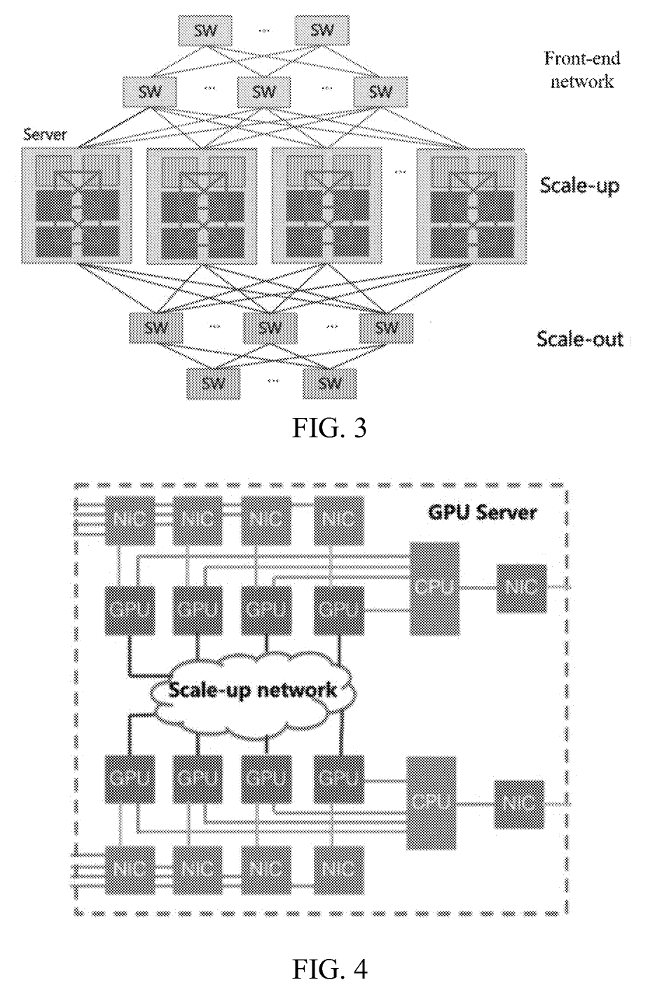

In addition, the OIO chiplet provided in an embodiment of the present disclosure can be applied in the system architecture of the AI computing cluster as shown in FIG. 3. As shown in FIG. 3, the system can include a front-end network, a back-end Scale-out network, and GPU servers.

The front-end network includes a plurality of interconnected switches (SW in FIG. 3) and CPUs in servers through Network Interface Cards (NICs) as an interface between the AI cluster and the external environment, configured to connect clients (such as user devices, application servers, or data sources) to the AI cluster. A main function of the front-end network is to receive input data and return processing results of GPU servers. The front-end network needs to support large-scale data transmission and usually adopts high-speed Ethernet technology. The front-end network is generally characterized by low latency and scalability.

The back-end Scale-out network includes a plurality of interconnected switches (SW in FIG. 3) and GPUs in servers through NICs, and is mainly configured for communication between GPU servers within the AI cluster, especially in distributed training scenarios. A purpose of the back-end Scale-out network is to implement high-performance, low-latency data exchange to support large-scale model training. The back-end Scale-out network supports parameter synchronization, gradient updates, and data sharing between GPUs servers.

The AI cluster can include a plurality of computing nodes, each computing node includes a plurality of GPU servers, and each GPU server includes a plurality of GPUs or other accelerator chips interconnected through a Scale-up network. The Scale-up network is mainly configured to implement interconnect within a computing node, such as communication between GPUs within a GPU server or communication between GPU servers. As shown in FIG. 4, FIG. 4 shows an architecture diagram of a single GPU server. The GPU server includes a plurality of GPUs, a plurality of CPUs, and a plurality of network interface cards (NICs). The plurality of GPUs is interconnected through a Scale-up network.

The GPU server is generally used for tasks requiring large-scale parallel computation, such as deep learning. Each GPU has its own computing capability, and a plurality of GPUs are connected to a back-end scale-out network through the NICs. The coordination with CPUs and NICs is required. The figure shows a plurality of GPUs connected to the CPUs, which are further connected to a front-end network through the NICs.

In an embodiment of the present disclosure, an OIO chiplet is provided for Scale-up network interconnection. In one embodiment, the OIO chiplet is disposed on a PCB board near the GPU chips, and after optical-to-electrical conversion directly on the board, the OIO chiplet is connected to a remote GPU through an optical fiber. In another embodiment, the OIO chiplet and the GPU can be packaged on a same substrate, appearing externally as an input/output port directly emitting light from the GPU.

The preferred embodiments of the present disclosure are described below with reference to the accompanying drawings of the specification. It should be understood that the preferred embodiments described herein are provided only for illustrating and explaining the present disclosure, not for limiting the present disclosure, and features of embodiments can be combined with each other where no conflict occurs.

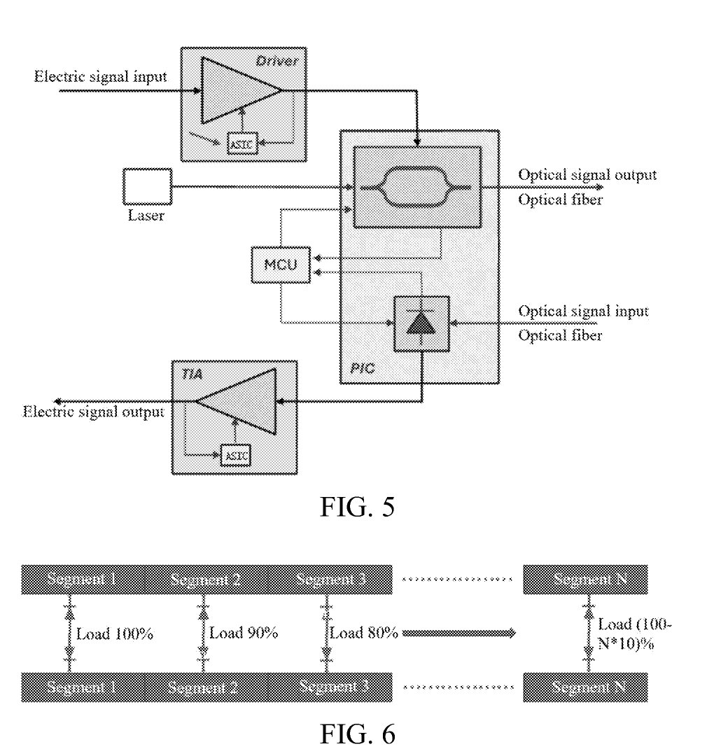

FIG. 5 is a schematic diagram of an OIO chiplet according to an embodiment of the present disclosure. As shown in FIG. 5, the OIO chiplet includes photonic chips, electronic chips, and a microcontroller chip.

The photonic chip (i.e., photonic integrated circuit, PIC) integrates a plurality of optical components onto a single chip. The micro-optical devices (such as waveguides, photonic modulators, photodetectors, and lasers) are fabricated on a silicon substrate or other materials, so that the functions including optical signal generation, transmission, modulation, and detection are implemented. Furthermore, data transmission and processing are performed by using optical signals instead of electrical signals, so that the OIO chiplet has the characteristics of high bandwidth, low latency, and low power consumption.

The laser serves as a continuous-wave light source and can be a distributed feedback (DFB) laser or a vertical-cavity surface-emitting laser (VCSEL). The laser can be disposed inside or outside the photonic chip. When the laser is disposed outside the photonic chip, the laser can be disposed on a PCB of the GPU corresponding to the OIO chiplet, or mounted on a panel of the GPU server. Alternatively, the laser can be disposed on an interposer of the OIO chiplet and connected to the photonic chip through an optical fiber or free-space coupling.

The waveguide is a core structure of the PIC chip, configured to guide optical signals to propagate within the chip. Common materials include silicon (Si), silicon nitride (SiN), and indium phosphide (InP).

The photodetector receives optical signals through the waveguide and a fiber array. Common materials include silicon Germanium (SiGe) and indium gallium arsenide (InGaAs). A splitter is configured to divide an optical signal into multiple outputs, and a coupler is configured to couple an optical signal from a fiber into an on-chip waveguide. A filter is configured to selectively transmit a specific wavelength and is commonly used in wavelength-division multiplexing (WDM) systems.

The photonic modulator modulates a continuous-wave light generated by the laser according to an input electrical signal and outputs the optical signal through the fiber array and waveguide. A continuous-wave light refers to a stable, continuous light output emitted by a laser or other light source, with intensity and frequency remaining constant over a period of time. Unlike pulsed light, a continuous-wave light has no temporal interruptions or modulation, and is a continuous and stable optical signal.

In this embodiment, the photonic modulator increases bandwidth through analog equalization. The photonic modulator includes a traveling-wave electrode and an active region. The traveling-wave electrode and the active region are two key components in the design of the electro-optic modulator.

The traveling-wave electrode is a specialized electrode structure configured to transmit radio-frequency signals and ensure that the electrical signal propagates at the same velocity as the optical signal within the modulator. The design purpose of the traveling-wave electrode is to synchronize the movement of the electric field with the optical field to improve modulation efficiency. A radio-frequency signal is input from an external source into the modulator, and through appropriate electrode design, the electric field is evenly distributed within the active region. The propagation velocity of the electrical signal is adjusted to match the group velocity of the optical signal.

The traveling-wave electrode typically includes a plurality of metal strips forming a microstrip line or coplanar waveguide. The length of the traveling-wave electrode is comparable to the length of the optical waveguide of the modulator to ensure uniform electric-field distribution across the entire modulation region. The electrode material is typically made of gold (Au) or another highly conductive metal. If the propagation velocity of the electrical signal does not match the group velocity of the optical signal, the modulation efficiency decreases. The traveling-wave electrode achieves phase-velocity matching by adjusting geometric dimensions (such as width and spacing) and material properties.

The active region is the core area of the electro-optic modulator for modulating the optical signal. The active region is an optical waveguide made of an electro-optic material, such as lithium niobate (LiNbO₃) or silicon-based materials. Under the action of an applied electric field, the refractive index of the material changes, thereby modulating the phase or amplitude of the optical signal. As an optical waveguide, the active region guides the optical signal to propagate within the chip. The active region is typically a miniaturized optical waveguide, with a width and a height precisely designed to support a specific optical mode. The material selection depends on the application scenario of the modulator. LiNbO₃ has an excellent electro-optic effect, suitable for high-performance modulators. The silicon-based materials are cost-effective and compatible with CMOS processes, suitable for large-scale production.

The active region can be considered a load for the traveling-wave electrode, as the active region imposes additional capacitance or resistance effects on the electrical signal. The load characteristics affect impedance matching and frequency response of the traveling-wave electrode, and therefore an optimized design is required. This embodiment provides analog equalization optimization for the active region.

Specifically, as shown in FIG. 6, the traveling-wave electrode is evenly divided into N segments, for example, 4 to 8 segments, with each segment having a length smaller than the microwave wavelength, such as each segment being λ/10 to λ/4. The capacitance or impedance of the active region in each segment varies according to a specific pattern, such as exponential decrease, to balance high-frequency loss and phase matching.

For example, in the case of impedance, in this embodiment, the impedance value of the active region in an N-th segment is (100-N×10)% of the impedance value in the first segment.

There are two methods for modifying the load of the active region. The first method is gradient doping of the active region; specifically, the capacitance value is adjusted by controlling the doping concentration of each segment through ion implantation. The second method is dynamic adjustment of electrical properties of the material by local heating or applying a bias voltage. In addition, the distributed resistive loads can be connected in series or parallel on the traveling-wave electrode to adjust equivalent impedance. Besides changing the structure of the active region, the impedance of each segment can also be modified by loading resistor-capacitor networks, such as integrating metal resistors or other types of resistive elements at different positions of the traveling-wave electrode, and by optimizing the resistor values and distribution positions, precise control of the active region load can be achieved, allowing flexible adjustment of load characteristics without significantly affecting optical performance. A variable capacitor can be introduced near the active region, and the capacitance value can be dynamically adjusted by controlling the bias voltage, suitable for application scenarios requiring dynamic load adjustment. Furthermore, the load of the active region can be adjusted by stacking multiple layers of materials with different properties. For example, one or more dielectric layers can be added above or below the active region to change the overall dielectric constant. Load characteristics can be optimized by adjusting the thickness and material parameters of each layer to achieve fine control of the load.

In this embodiment, segmented adjustment of the traveling-wave electrode load compensates for high-frequency signal attenuation and flattens the bandwidth of the photonic modulator. The larger the number of segments N, the higher the resolution of bandwidth equalization of the photonic modulator. The load of each segment is lower than that of the preceding segment, and the high-frequency portion is elevated correspondingly.

The electronic chip includes a driver amplifier, a transimpedance amplifier, and application-specific integrated circuit. The driver amplifier provides a driving signal for the photonic modulator, and the transimpedance amplifier amplifies the electrical signal generated by the photodetector. Two application-specific integrated circuits are provided, one is to control the transimpedance amplifier and the other is to control the driver amplifier.

The driver amplifier is one of the core components for implementing optical signal modulation. The main function of the driver amplifier is to amplify the input electrical signal to a sufficient power level to drive the photonic modulator. In the photonic chip, the main tasks of the driver amplifier include: amplifying the input low-power electrical signal to a radio-frequency power level sufficient to drive the photonic modulator or laser; ensuring impedance matching between the amplifier output and the photonic modulator or laser input to maximize power transfer and reduce reflection; providing a flat gain curve to maintain good performance across the entire operating frequency range; and reducing nonlinear distortion to prevent adverse effects on the modulation signal waveform. In the present disclosure, higher gain is achieved by cascading multi-stage amplifiers. The present disclosure integrates the driver amplifier and the photonic modulator through 3D packaging, so that signal transmission loss is reduced, and the overall performance is improved. Compared with a conventional optical transceiver driver amplifier, a chip-level driver amplifier has higher bandwidth, higher linearity, smaller size, and lower power consumption.

A transimpedance amplifier is one of the indispensable core components in an optical receiving system, and a main function of the transimpedance amplifier is to convert a weak current signal output by a photodetector into a voltage signal and amplify the voltage signal. A transimpedance amplifier is a circuit that converts an input current signal into an output voltage signal, and a core characteristic of the transimpedance amplifier is described by transimpedance defined as a ratio of a change in output voltage to a change in input current. Ideally, an input impedance of the transimpedance amplifier approaches zero to receive the current signal output by the photodetector to a maximum extent. Similar to the driver amplifier, the transimpedance amplifier in the present disclosure achieves higher gain and bandwidth by using a plurality of amplifier units.

A transimpedance-amplifier control application-specific integrated circuit is a specially designed integrated circuit configured to optimize and control performance of the transimpedance amplifier and the photodetector. The transimpedance-amplifier control application-specific integrated circuit can dynamically adjust a gain of the transimpedance amplifier to adapt to different input signal intensities and adjust the attenuators at the input of the photodetector. The transimpedance-amplifier control application-specific integrated circuit reduces a gain under a strong-signal condition to avoid saturation, and increases the gain under a weak-signal condition to enhance sensitivity. A bandwidth of the transimpedance amplifier is inversely proportional to a gain of the transimpedance amplifier, and the transimpedance-amplifier control application-specific integrated circuit can optimize a bandwidth-gain balance according to an application requirement. The transimpedance-amplifier control application-specific integrated circuit includes a noise filtering module and a noise suppression module, and reduces influence of thermal noise, shot noise, and other interference on a signal. The transimpedance-amplifier control application-specific integrated circuit provides control to the attenuators at the input of the photodetectors to reduce the polarization dependent loss (PDL) of the photonic chip and avoid overloading of input optical signals. The transimpedance-amplifier control application-specific integrated circuit provides a precise bias voltage or bias current to a photodetector and active components in the transimpedance amplifier, and ensures operation of the photodetector and the active components in an optimal state.

A driver-amplifier control application-specific integrated circuit is configured to optimize and control performance of the driver amplifier. The driver-amplifier control application-specific integrated circuit can dynamically adjust a gain of the driver amplifier to adapt to different input signal strengths and load requirements. In some application scenarios, the driver amplifier may automatically adjust the gain according to real-time conditions, such as temperature or load variations. A bandwidth of the driver amplifier determines a signal frequency range that the driver amplifier can process. The driver-amplifier control application-specific integrated circuit can ensure that the driver amplifier has good performance within a target frequency range by optimizing circuit parameters, such as a feedback network and compensation capacitors. The driver amplifier may introduce nonlinear distortion that affects output signal quality, and the driver-amplifier control application-specific integrated circuit includes a linearization algorithm or predistortion technique to reduce nonlinear effects. The driver-amplifier control application-specific integrated circuit provides overvoltage, overcurrent, and electrostatic discharge protection to prevent damage to the driver amplifier or a load due to external interference or abnormal conditions. The driver-amplifier control application-specific integrated circuit provides precise automatic bias control of the photonic modulator in the photonic chip, ensuring operation of the photonic modulator in an optimal state.

In the amplifier circuit, a frequency response characteristic directly affects signal transmission quality. When load characteristics change, high-frequency gain reduction and low-frequency gain insufficiency can occur simultaneously. This nonlinear frequency response causes a significant fluctuation in the bandwidth curve of the output signal. In a high-frequency operating state, parasitic parameters of the amplifier circuit begin to exert significant influence. When the load impedance decreases, a low-pass filtering network formed by a transistor output capacitance and the load impedance exhibits a significantly reduced cutoff frequency. Taking a typical common-emitter amplifier circuit as an example, a high-frequency gain can be expressed as: Av_HF=-gm(RL||ro)/(1+jω(Cob+Cμ)RL), where Av_HF represents high-frequency gain, gm represents transconductance, ro represents output impedance, Cob represents output capacitance, and RL represents load impedance. A dominant pole frequency fp=1/(2πRL(Cob+Cμ)). When the load impedance RL decreases, the dominant pole frequency shifts toward low frequency, causing high-frequency gain to begin rolling off prematurely. In addition, the effects of distributed inductance at frequencies above MHz cannot be ignored. The parasitic inductance of load lines (approximately 1-10 nH/cm) and distributed capacitance of a circuit board form a resonant loop, which can cause abnormal fluctuations in the gain curve.

In a low-frequency range (typically <1 kHz), the reactance of coupling capacitors increases significantly, resulting in an increased effective impedance of the signal path. For an amplifier circuit using resistive-capacitive coupling, a low-frequency cutoff is determined by: fL = 1/(2π(Ro+RL)Cc), where fL represents a low-frequency cutoff, Ro represents an output impedance of a previous stage, and Cc represents a coupling capacitor. When RL decreases, an equivalent series impedance decreases, causing the low-frequency cutoff to shift toward high frequency and resulting in reduced effective low-frequency gain.

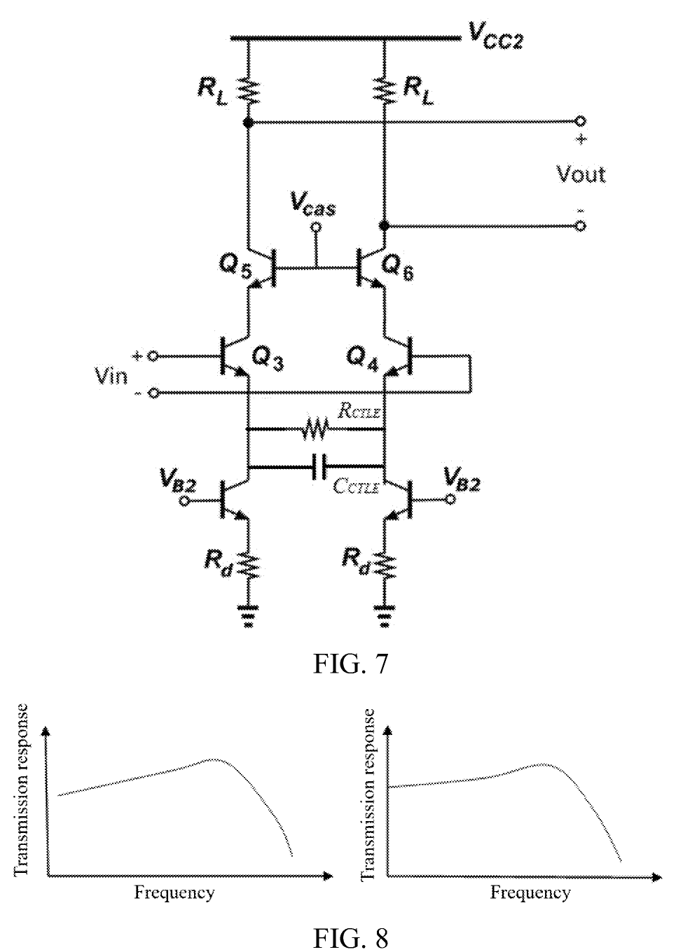

To improve the foregoing frequency response, in this embodiment, the transimpedance-amplifier control application-specific integrated circuit and the driver-amplifier control application-specific integrated circuit are each provided with analog equalization circuits. Specifically, an equalizer is configured in each amplifier stage of the driver amplifier and the transimpedance amplifier. FIG. 7 shows a principle of equalization for an amplifier circuit, in which an R_{CTLE} equalizer and a C_{CTLE} equalizer can be configured to adjust gain bandwidth. In this embodiment, a target of equalization control is to adjust signal gain in different frequency ranges, so that an overall bandwidth curve becomes flat. The equalization control through the amplifiers of different stages can compensate bandwidth curves for different loads, thereby obtaining a relatively flat bandwidth and a desired curve.

The R_{CTLE} equalizer is composed of resistors and capacitors and is generally configured to compensate for losses in a transmission line. At high frequencies, the capacitive impedance is low, allowing more high-frequency signals to pass. At low frequencies, the resistive elements dominate, limiting gain of low-frequency signals. The R_{CTLE} equalizer increases high-frequency gain and extends the bandwidth of the amplifier. The R_{CTLE} equalizer compensates for insertion loss in the transmission line. The C_{CTLE} equalizer achieves signal equalization through capacitive coupling. The C_{CTLE} equalizer enhances gain of high-frequency signals by using frequency-selective characteristics of capacitors. The C_{CTLE} equalizer reduces gain of low-frequency signals to avoid overload or distortion. The C_{CTLE} equalizer optimizes transmission characteristics of high-frequency signals, thereby improving linearity and stability of the amplifier.

FIG. 8 shows the bandwidth expansion effect of the photonic chip and the electronic chip after the equalization technique is adopted. It can be seen from this figure that the equalization of the photonic chip and the electronic chip mainly enhances high-frequency response, thereby increasing system bandwidth, which allows the chiplet to operate without a digital signal processor (DSP), and significantly reduces power consumption, cost, and latency of optical interconnection.

The microcontroller chip is connected to feedback terminals of the photodetector and the photonic modulator, and sends control signals to the photodetector and the photonic modulator to adjust output. The microcontroller chip manages and coordinates operation of the entire chiplet. The microcontroller chip also controls and monitor operational states of the laser, the modulator, and the photodetector to ensure high-quality signal transmission. The performance degradation caused by temperature variation or aging effects is compensated through real-time monitoring and adjustment. The microcontroller chip, the transimpedance-amplifier control application-specific integrated circuit, and the driver-amplifier control application-specific integrated circuit can achieve complementary functionality.

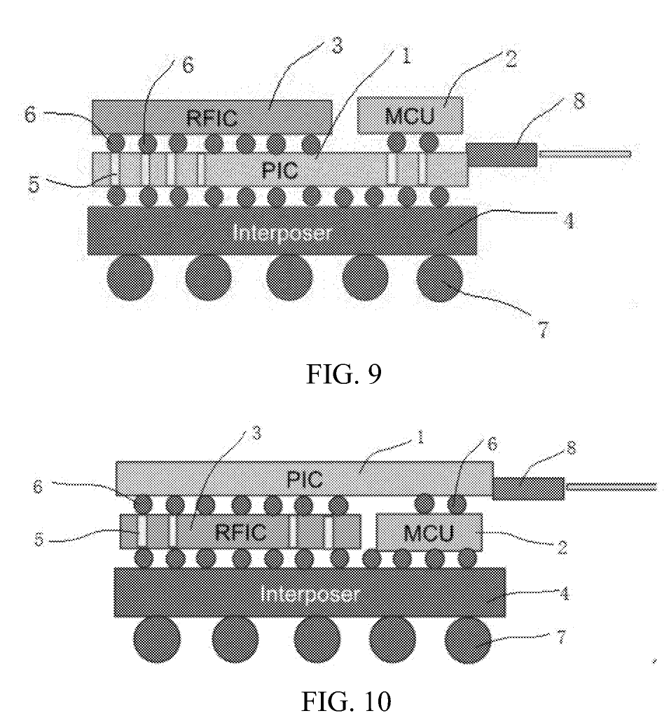

As shown in FIGS. 9 and 10, in this embodiment, three-dimensional (3D) packaging technology is adopted. The 3D packaging technology stacks a plurality of chips, such as processors, memory, and sensors, together and achieves inter-chip communication through vertical interconnection technology. The 3D packaging technology overcomes limitations of traditional planar layout, shortens distances between chips, reduces signal transmission latency, and improves overall performance. The photonic chip 1, the electronic chip 3, and the microcontroller chip 2 are stacked on the interposer 4 in a form of bare die, and inter-chip communication is implemented using through-silicon vias 5. Bare die refers to an unpackaged chip with an exposed circuit structure. Bare die serves as a fundamental building unit, and an unpackaged characteristic of the bare die provides significant advantages: a thickness is controlled within 50-200 μm, a volume is reduced by 90% compared with a traditionally packaged chip, and a signal transmission path is shortened to a micrometer level, thereby reducing 30-50% power loss caused by parasitic effects. In this embodiment, stacking in a bare die form is adopted, thereby minimizing additional volume and power consumption caused by packaging to a maximum extent. An interposer 4 serves as a neural center of 3D packaging, and high-density routing is achieved by adopting a silicon-based material or a glass-based material. Taking Chip-on-Wafer-on-Substrate (CoWoS) technology from Taiwan Semiconductor Manufacturing Company, Ltd. as an example, an interposer manufactured with a 65 nm process achieves a routing density of 1 μm/1 μm line width/line spacing and integrates more than 10,000 through-silicon via channels. In this embodiment, the interposer 4 is configured to carry a plurality of bare die and provide a high-density interconnection network. The through-silicon via technology enables direct electrical connection during bare die stacking, thereby significantly shortening a signal path and reducing delay. Bumps 6 are further provided between a photonic chip 1 and an electronic chip 3 for connection. The bumps 6 are one of important structures for implementing inter-chip interconnection. The bumps are configured to connect chips at different levels or provide an electrical and mechanical connection between a chip and an interposer or a substrate. The interposer 4 is packaged on a PCB board through a ball grid array or land grid array package 7. Reference numeral 8 denotes a fiber array.

Two packaging manners are provided herein. In a first manner as shown in FIG. 9, the photonic chip 1 is disposed on the interposer 4, through-silicon vias are disposed in the photonic chip 1, and a microcontroller chip 2 and an electronic chip 3 are disposed on the photonic chip 1.

In a second manner as shown in FIG. 10, the electronic chip 3 and the microcontroller chip 2 are disposed on the interposer 4, through-silicon vias are disposed in the electronic chip 3, and the photonic chip 1 is disposed on the electronic chip and the microcontroller chip.

The communication between chips in a same plane is implemented through metal interconnection lines on the interposer. Vertical signal transmission between stacked chips is implemented by through-silicon vias (TSVs).

In FIG. 9 and FIG. 10, only one electronic chip and one photonic chip are illustrated. In reality, there can be multiple electronic chips and photonic chips in one package.

The chips stacked together are directly connected by forming conductive channels penetrating through a silicon wafer or a chip, thereby significantly improving signal transmission efficiency and system integration level. The chips are vertically stacked, so that the overall size of the system is significantly reduced, the signal transmission paths are shortened, and the parasitic effects and energy loss are reduced.

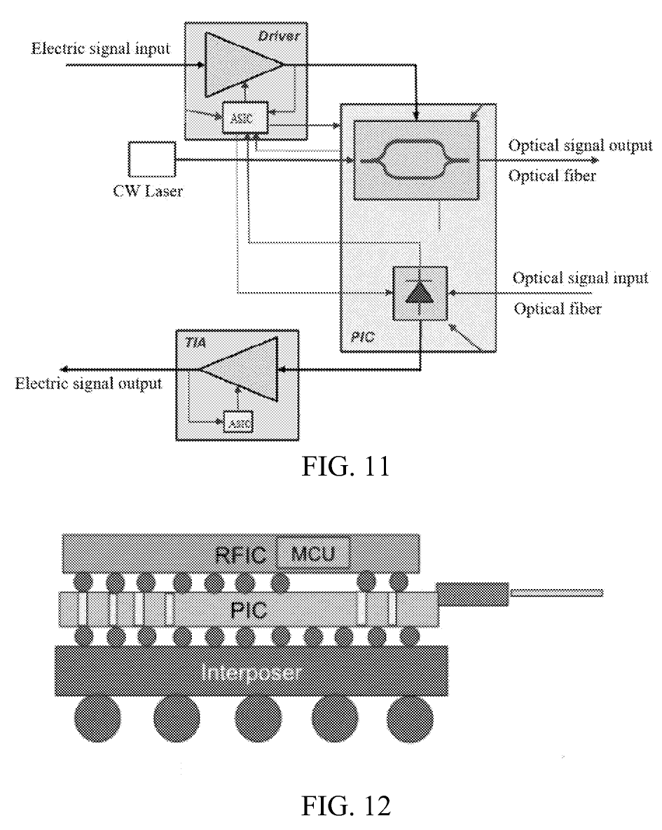

FIG. 11 is a schematic diagram of another OIO chiplet according to an embodiment of the present application. A basic structure of this OIO chiplet is substantially the same as that of a first OIO chiplet, and a difference lies in that a microcontroller unit is integrated inside an electronic chip in a form of an application-specific integrated circuit, and further integrated inside a driver amplifier, and integrated into a driver-amplifier control application-specific integrated circuit. In this architecture, an application-specific integrated circuit is configured to implement fixed control logic or an algorithm, including bandwidth equalization, temperature compensation, or bias control of a modulator.

Although the MCU has programmability, in some scenarios, the application-specific integrated circuit has advantages as follows:

high performance: the application-specific integrated circuit is optimized for a specific task, and operation speed is higher;

low power consumption: circuit design of the application-specific integrated circuit is more efficient, and power consumption is lower;

high reliability: fixed functions of the application-specific integrated circuit reduce possibility of software errors; and

small size: high integration characteristics of the application-specific integrated circuit can significantly reduce chip area.

Once the design of the application-specific integrated circuit is completed, modification cannot be performed, and customization is required for each photonic modulator.

The photonic chip and the electronic chip are stacked on the interposer in a form of bare die, and inter-chip communication is implemented using through-silicon vias.

The 3D packaging technology is adopted herein, the photonic chip and the electronic chip are stacked on the interposer in a form of bare die, and inter-chip communication is implemented using through-silicon vias.

Similarly, two packaging manners are provided herein. In a first manner as shown in FIG. 12, the photonic chip is disposed on the interposer, through-silicon vias are disposed in the photonic chip, and the microcontroller chip and the electronic chip are disposed on the photonic chip.

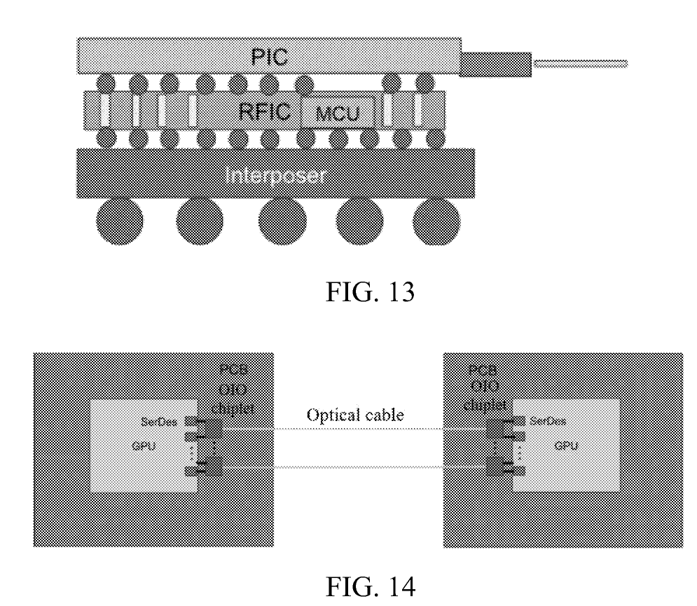

In a second manner as shown in FIG. 13, the electronic chip and the microcontroller chip are disposed on the interposer, through-silicon vias are disposed in the electronic chip, and the photonic chip is disposed on the electronic chip and the microcontroller chip.

Corresponding to the OIO chiplet described above, an embodiment of the present disclosure further provides an AI computing cluster, where the AI computing cluster includes a plurality of nodes, each node includes a plurality of GPUs, CPUs, and dedicated interfaces, and an internal schematic of each node is shown in FIG. 2. The nodes are interconnected through a Scale-out network, the nodes are internally interconnected through a Scale-up network, GPUs within the nodes are interconnected through a fiber array and the OIO chiplet described above, and the fiber array is connected to a corresponding OIO chiplet.

For a connection manner between an OIO chip and an optical fiber, a direct coupling manner can be adopted. The optical fiber is physically coupled directly to an optical module or an optical component on the OIO chip without an additional pluggable interface. During a chip packaging stage, the optical fiber is aligned to an optical waveguide or an optical transceiver on the chip with micron-level or nanometer-level precision. The optical fiber is permanently connected to the chip using gluing, soldering, or other fixing technologies. The direct coupling manner can reduce reflection and scattering of signals at an interface, thereby reducing transmission loss. High reliability is achieved, the movable components are not required, and possibility of the mechanical failure is reduced. Compact design is achieved, additional interface hardware is not required, and space is saved.

As shown in FIG. 14, the OIO chiplet and the corresponding GPU can be disposed on the same PCB, where the OIO chiplet is packaged on the PCB through a ball grid array or land grid array. In this architecture, the OIO chiplet is placed on the PCB close to the GPU to reduce loss and latency along the signal transmission path. The high-speed optical signal transmission capability of the OIO chiplet combined with the powerful computing capability of the GPU achieves higher data throughput and lower latency, thereby improving overall system performance. The OIO chiplet and the GPU are integrated on the same PCB, so that the number of external connectors and cables is reduced, the system design is simplified, and the manufacturing cost is reduced. The PCB routing and thermal design are optimized, so that the system reliability and stability are enhanced, and the service life is prolonged.

In addition, the GPU and a corresponding OIO chiplet may be packaged on a same substrate. The OIO chiplet and the GPU are disposed on the same silicon interposer, and the interconnection is implemented through high-density metal interconnects. Externally, the OIO is a direct optical input/output port from the GPU, and is a highly integrated design solution. This architecture not only enhances system compactness but also further optimizes data transmission efficiency and performance.

The OIO chiplet and the AI computing cluster provided in the embodiments of the present disclosure, compared with a copper cable interconnection solution, can significantly increase interconnection distance and expand the Scale-up network scale of GPU interconnection. Compared with a conventional pluggable optical transceiver interconnect solution, the OIO chiplet has the advantages of low latency, low power consumption, high bandwidth density, and high reliability. The OIO chiplet can adapt to diverse requirements of AI chips and systems and may be integrated into systems by customers according to specific requirements, such as NPO (Near-Packaged Optics) or CPO (Co-Packaged Optics) systems, thereby improving computing efficiency.

It should be noted that, although several units or subunits of the apparatus are mentioned in the detailed description above, such division is merely exemplary and not mandatory. In practice, according to the embodiments of the present disclosure, features and functions of two or more units described above can be implemented within a single unit. Conversely, features and functions of a single unit described above can be further divided and implemented by a plurality of units.

It is apparent to those skilled in the art that various modifications and variations can be made to the embodiments of the present disclosure without departing from the spirit and scope of the embodiments of the present disclosure. Therefore, if such modifications and variations fall within the scope of the claims of the present disclosure and the equivalents thereof, the present disclosure intends to encompass these modifications and variations.

What is claimed is:

1. An OIO chiplet, comprising:
photonic chips, wherein the photonic chip comprises photodetectors and photonic modulators, the photodetector is configured to receive an optical signal, the photonic modulator modulates an input continuous-wave light according to an input electrical signal and outputs the optical signal, and the photonic modulator improves bandwidth through analog equalization;
electronic chips, wherein the electronic chip comprises driver amplifiers, transimpedance amplifiers, and application-specific integrated circuits, the driver amplifier provides a driving signal for the photonic modulator, the transimpedance amplifier amplifies an electrical signal generated by the photodetector, and the application-specific integrated circuit comprises an analog equalization module configured to improve linearity of the driver amplifier and the transimpedance amplifier;
a microcontroller chip, wherein the microcontroller chip is connected to feedback terminals of the photodetector and the photonic modulator, and sends control signals to the photodetector and the photonic modulator to adjust output; and
an interposer, wherein the photonic chip, the electronic chip, and the microcontroller chip are stacked on the interposer in a form of bare die, and inter-chip communication is implemented using through-silicon vias or through-mold vias.

2. The OIO chiplet according to claim 1, wherein the photonic modulator comprises a traveling-wave electrode and an active region, the traveling-wave electrode is divided into a plurality of segments having a same length, and each segment of the traveling-wave electrode loads an active region having a different capacitance or impedance to form a gradient.

3. The OIO chiplet according to claim 2, wherein the analog equalization module comprises a plurality of equalizers, the driver amplifier and the transimpedance amplifier comprise a plurality of cascaded amplification stages, and each amplification stage is provided with one equalizer.

4. The OIO chiplet according to claim 2, wherein the photonic chip is disposed on the interposer, through-silicon vias are disposed in the photonic chip, and the microcontroller chip and the electronic chip are disposed on the photonic chip.

5. The OIO chiplet according to claim 2, wherein the electronic chip and the microcontroller chip are disposed on the interposer, through-silicon vias are disposed in the electronic chip, and the photonic chip is disposed on the electronic chip and the microcontroller chip.

6. An OIO chiplet, comprising:
photonic chips, wherein the photonic chip comprises photodetectors and photonic modulators, the photodetector is configured to receive an optical signal, the photonic modulator modulates an input continuous-wave light according to an input electrical signal and outputs the optical signal, and the photonic modulator improves bandwidth through analog equalization;
electronic chips, wherein the electronic chip comprises driver amplifiers, transimpedance amplifiers, and application-specific integrated circuits, the driver amplifier provides a driving signal for the photonic modulator, the transimpedance amplifier amplifies an electrical signal generated by the photodetector, and the application-specific integrated circuit comprises a microcontrol circuit and an analog equalization module configured to improve linearity of the driver amplifier and the transimpedance amplifier, wherein the microcontrol circuit is connected to feedback terminals of the photodetector and the photonic modulator, and sends control signals to the photodetector and the photonic modulator to adjust output; and
an interposer, wherein the photonic chip and the electronic chip are stacked on the interposer in a form of bare die, and inter-chip communication is implemented using through-silicon vias or through-mold vias.

7. The OIO chiplet according to claim 6, wherein the photonic modulator comprises a traveling-wave electrode and an active region, the traveling-wave electrode is divided into a plurality of segments having a same length, and each segment of the traveling-wave electrode loads an active region having a different capacitance or impedance to form a gradient.

8. The OIO chiplet according to claim 7, wherein the analog equalization module comprises a plurality of equalizers, the driver amplifier and the transimpedance amplifier comprise a plurality of cascaded amplification stages, and each amplification stage is provided with one equalizer.

9. The OIO chiplet according to claim 7, wherein the photonic chip is disposed on the interposer, through-silicon vias are disposed in the photonic chip, and the electronic chip is disposed on the photonic chip.

10. The OIO chiplet according to claim 6, wherein the electronic chip is disposed on the interposer, through-silicon vias are disposed in the electronic chip, and the photonic chip is disposed on the electronic chip.

11. An AI computing cluster, comprising a plurality of nodes, wherein each node comprises a plurality of GPUs, the nodes are interconnected through a Scale-out network, the nodes are internally interconnected through a Scale-up network, GPUs within the nodes are interconnected through a fiber array and the OIO chiplet according to claim 1, and the fiber array is connected to a corresponding OIO chiplet.

12. The AI computing cluster according to claim 11, wherein the OIO chiplet and a corresponding GPU are disposed on a same PCB, and the OIO chiplet is packaged on the PCB through a ball grid array or land grid array.

13. The AI computing cluster according to claim 11, wherein the GPU and a corresponding OIO chiplet are packaged on a same substrate.
